(19) United States
(12) Patent Application Publication
(10) Pub. No.: US 2026/0130047 A1
(43) Pub. Date: May 7, 2026

(54) LIGHT-EMITTING DISPLAY DEVICE, METHOD FOR MANUFACTURING SUCH A DEVICE AND LIGHT-EMITTING DISPLAY SYSTEM

(71) Applicants: COMMISSARIAT À L'ÉNERGIE ATOMIQUE ET AUX ÉNERGIES ALTERNATIVES, PARIS (FR); MICROOLED, GRENOBLE CEDEX 09 (FR)

(72) Inventors: Clément BALLOT, GRENOBLE CEDEX 09 (FR); Adrien GASSE, GRENOBLE CEDEX 09 (FR); Gunther HAAS, GRENOBLE CEDEX 09 (FR)

(21) Appl. No.: 19/378,606

(22) Filed: Nov. 4, 2025

(30) Foreign Application Priority Data
Nov. 4, 2024 (FR) FR2412040

(51) Int. Cl. H10K 59/12; H10K 59/122; H10K 71/00

(52) U.S. Cl. CPC H10K 59/1201; H10K 59/122; H10K 71/621

(57) ABSTRACT

A method for manufacturing a light-emitting display device from islands separated by a trench, the method including filling the trench with an insulating structural element; forming a protective strip only partly covering each of the islands and overlapping the structural element; partially etching the structural element so as to form a pillar under the protective strip such that the same has cantilevered parts; and depositing an organic layer resulting in two distinct and separate portions, a first portion continuously extending over each island and over the protective strip, and a second portion extending over the substrate.

### CROSS-REFERENCE TO RELATED APPLICATIONS

This application claims priority to French Patent Application No. 2412040, filed Nov. 4, 2024, the entire content of which is incorporated herein by reference in its entirety.

### FIELD

The technical field of the invention is that of optoelectronic devices, and more particularly that of matrix display devices with organic light-emitting layers.

The present invention relates to a method for manufacturing an OLED (Organic Light-Emitting Diode) type light-emitting display device, as well as a method for manufacturing such a device.

The present invention finds beneficial application in the manufacture of display screens for electronic devices, and in particular for the manufacture of high-resolution colour display screens such as AMOLED (Active Matrix Organic Light-Emitting Diodes) display screens. The term “high resolution” designates pixels with a size smaller than 15 μm.

### BACKGROUND

In the field of matrix display devices with organic light-emitting layers, OLED type matrix microdisplays having pixels arranged with a pitch of less than 20 μm, typically between 4 μm and 12 μm are known.

When this type of matrix display is in colour, each pixel is subdivided into sub-pixels of different colours (typically three, having red, green and blue colours) which work together to make the pixel emit the desired colour. The surface of the sub-pixels can be rectangular, square, or other shapes (for example octagonal), and their size may depend on the colour. The typical size of sub-pixels can range from 1 μm to 20 μm.

Each sub-pixel is generally formed by several superimposed layers, including a lower electrode (the anode) deposited onto a common substrate, several organic layers (at least one of which is emissive) forming an OLED stack on each lower electrode, and an upper electrode (the cathode).

Documents FR3079909A1 and US2023/0041252A1 describe structures for forming OLED pixels (or OLED sub-pixels) of such a small size with improved industrial reliability.

These structures have the common benefit of allowing smooth discretisation of the OLED stack and cathode to form pixels (or sub-pixels). The term “smooth discretisation” designates a structuring method that preserves performance of the OLED stack.

In particular, solutions provided consist in performing discretisation of the OLED stack in a way other than through masking and removal steps, which generally require environments (humidity, temperatures above 90° C., solvents, ultraviolet light, etc.) that are harmful to organic materials.

Document FR3079909 A1 thus describes a first OLED display device in which the lower electrodes of each sub-pixel are separated from each other by an insulating wall rising vertically from the substrate. Each wall acts as a separator between two neighbouring sub-pixels.

The same document FR3079909 describes a second device in which the insulating walls are replaced with trenches into which an insulating layer is deposited.

The insulating walls and trenches are formed before the OLED stack is deposited by thermal evaporation and play the same role. As the evaporation deposition technique is predominantly directional, the OLED stack is in an embodiment deposited onto the horizontal walls of the device, and not onto the side walls of the insulating walls or trenches. The OLED stack is thus broken up (or discretised) at the insulating walls or trenches.

However, in practice, directivity of the deposition of the OLED stack is never total. Organic particles can therefore also be deposited onto the side walls of the insulating walls or trenches. And these particles are undesirable because they degrade insulation (electrical, optical) between the sub-pixels. Neighbouring sub-pixels can then interact with each other, for example through capacitive coupling or parasitic currents. These phenomena, known as crosstalk, lead to a degradation in performance of the display device. These phenomena are exacerbated when the sub-pixels are so-called “tandem” organic light-emitting diodes, i.e. when the sub-pixels comprise several OLED stacks stacked and connected in series by virtue of interconnection layers.

Document US2023/0041252A1 offers a solution to this problem by describing sub-pixel separators that are disposed on a substrate and have a mushroom-shaped structure (or “hang-over” according to the terminology used in this document). More precisely, this mushroom-shaped structure comprises a lower part with sloping sides, forming the stem of the mushroom. It also comprises an upper part, wider than the lower part, which masks a region of the substrate. This upper part forms the cap of the mushroom.

The sub-pixels are formed once the mushroom structures are in place. The OLED stack is then deposited onto these structures and broken up at the upper parts. Breaking up the OLED stack is performed with satisfactory reliability since the organic material cannot be deposited onto the region of the substrate masked by the upper part or onto the side walls of the mushroom structure (the lower part is not accessible from above because it is hidden by the upper part). Thus, the degree of directivity of the OLED stack deposition is irrelevant.

However, these mushroom-shaped structures are particularly complex to make and not very compact (vertically, they are in the order of 1 μm high). Furthermore, making a common upper electrode (cathode) requires the use of specific equipment to deposit the material at the desired angle. This indeed involves performing deposition of a conductive layer under the upper part of the mushroom structures at a very specific angle, determined by the tilt of the lower parts. It is therefore neither easy nor economically beneficial to make use of such a manufacturing method.

There is therefore still a need for a method for manufacturing OLED display devices with improved resolution that is less costly and simpler to implement.

### SUMMARY

An aspect of the invention provides a solution to the problems discussed previously by allowing a common upper electrode to be formed between several pixels (the upper electrode generally being the common cathode) using separation structures integrated into the lower electrodes of the pixels (these often being the anodes of these pixels). For this, one or more aspects of the invention make it possible to discretise the lower parts of two adjacent pixels by providing a continuous surface between these two pixels to form a layer of organic material and a continuous upper electrode.

One aspect of the invention relates to a method for manufacturing a light-emitting display device from a precursor, said precursor comprising a plurality of islands disposed on a substrate, each island comprising a support layer extending over the substrate; and a conductive layer extending over the support layer, the islands being separated two by two by a trench, the method comprising:
filling each trench separating the islands with a structural element providing electrical insulation between the islands, for each trench, filling being performed until said structural element reaches the top of the islands separated by said trench;
forming at least one protective strip, each protective strip connecting two islands between each other by overlapping the trench separating said two islands and by covering the structural element extending in the trench, each protective strip only partly covering each of the two islands it connects;
partially etching the structural element selectively with respect to each protective strip and relative to the conductive layers of the islands, partially etching comprising at least one isotropic etching phase, partially etching being performed so as to retain only a portion of the structural element disposed under each protective strip, and said portion forming a pillar for each protective strip, partially etching further being performed so that at least one part of each protective strip extends in a cantilevered fashion beyond the pillar supporting it; and
anisotropically depositing an organic layer at an angle substantially perpendicular to the substrate, resulting in two distinct and separate portions of the organic layer, including a first portion continuously extending over each island and each protective strip, and a second portion extending over the substrate, a thickness of the organic layer being selected so that the second portion of the organic layer does not reach said at least one cantilevered part of each protective strip.

Each island comprises a conductive layer that can form a lower electrode. The use of a support layer for each island makes it possible to raise this conductive layer above the substrate. The protective strip extends from one island to another and is supported by the insulating element. Each protective strip forms a bridge between two islands. This bridge allows an organic layer to be formed continuously over the islands and without any discontinuities between the islands. An additional conductive layer can then be deposited onto this organic layer so as to form a continuous upper electrode without any discontinuities between the islands. This allows a common upper electrode (for example a common cathode) to be formed for all the islands.

Removing part of the structural element under each protective strip then allows a bridge to be formed with cantilevered sections vertically above the substrate in the trench. By “cantilevered part”, it is meant a suspended or support-less part. There is therefore a discontinuity between the edge of the bridge and the substrate. Consequently, depositing an organic material onto the islands and bridges results in two distinct portions of said organic material, with no electrical contact between them. During deposition, a portion of the organic material is deposited onto each protective strip, especially on the cantilevered parts of each protective strip, while another portion falls between the islands, onto the substrate. The presence of the cantilevered parts breaks continuity between the protective strips and the substrate. As long as the thickness of the deposited organic material does not allow the portion extending over the substrate to reach the cantilevered parts, the two portions of organic material (the one on the bridges and islands, and the one on the substrate) remain distinct and without physical and electrical continuity.

Thus, it is possible to form an organic layer and an electrode common to several islands, without risk of short-circuiting with the lower electrodes and without risk of electrical contact with surrounding elements (such as an additional island not intended to be connected to these islands). This makes it possible to produce a better-quality display device and as well simplifies its manufacture. Indeed, a full-wafer deposition, even if imperfectly directional, can be used to form the active elements and upper electrodes of the final pixels.

Furthermore, when the device comprises more than two islands, separated from each other by trenches, it is then possible to connect the islands two by two with a bridge as provided previously, to form a common organic layer and/or a common cathode. It is not necessary to provide additional separation elements to ensure electrical insulation between the final pixels. It is then possible to form distinct chains of pixels, each chain having a common cathode. This reduces the number of steps to be implemented relative to prior art solutions. The manufacturing method is thus simpler and faster to implement.

Beneficially, partially etching the structural element is performed so that the lateral gap between the at least one cantilevered part of each protective strip relative to the pillar supporting it is strictly greater than 100 nm.

Beneficially, for each trench, filling is performed until the structural element goes beyond the conductive layers of the two islands separated by said trench by a height of between 10 nm and 100 nm.

Beneficially, each island comprises, prior to filling each trench, a sacrificial layer extending over the conductive layer, filling of each trench with the structural element being performed such that the structural element reaches the top of the sacrificial layers extending over the islands.

Beneficially, the method further comprises, after filling each trench and before forming each protective strip, etching the sacrificial layer of each island selectively with respect to the structural element, etching being performed with stopping at said conductive layer of said island.

Beneficially, for each trench, filling with the structural element comprises:
depositing a layer of electrically insulating material so as to completely fill said trench;
polishing the layer of electrically insulating material with stopping at the sacrificial layer of each island.

Beneficially, for each trench, filling with the structural element comprises the following steps of:
conformally depositing a dielectric layer in said trench;
depositing a layer of filling material onto the dielectric layer so as to completely fill said trench;
polishing the dielectric layer and the filling layer with stopping at the sacrificial layer of each island.

Beneficially, the filling material is amorphous silicon or polycrystalline silicon.

Beneficially, the method comprises, prior to forming each protective strip, creeping or swelling the structural element so that it goes over a portion of the conductive layer of each island, by forming at least one continuous, ridge-less free surface extending from the conductive layer of one of the islands to the conductive layer of another island, each free surface having a slope, measured relative to the substrate, of between −45 degrees and 45 degrees and for example between −20 degrees and +20 degrees.

Beneficially, each protective strip is electrically insulating.

Beneficially, partially etching the structural element comprises at least one anisotropic etching phase and at least one isotropic etching phase, for example alternately, each anisotropic etching phase being performed with a directivity substantially perpendicular to the substrate.

Beneficially, the method comprises, after depositing the organic layer, anisotropically depositing an additional conductive layer, resulting in two distinct and separate portions of the additional conductive layer, including a first portion of the additional conductive layer continuously extending over the first portion of the organic material layer, and a second portion of the additional conductive layer extending over the second portion of the organic layer, a deposition thickness of the additional conductive layer being selected such that the second portion of the additional conductive layer does not reach said at least one cantilevered part of each protective strip.

Beneficially, partially etching the structural element is further performed so as to partially etch the support layer of each island such that, for each island, at least one part of the conductive layer of said island extends in a cantilevered fashion beyond the support layer of said island.

Another aspect of the invention relates to a light-emitting display device comprising a plurality of islands disposed on a substrate, each island comprising a support layer extending over the substrate and a conductive layer extending over the support layer, the device comprising:
at least one trench separating the islands two by two;
at least one protective strip, each protective strip connecting two islands to each other by overlapping the trench separating said two islands and by covering the pillar extending into the trench, each protective strip only partly covering each of the two islands;
at least one pillar at least partly filling a trench and electrically insulating the islands separated by said trench, each pillar reaching or going beyond the top of the two islands separated by said trench, each pillar being disposed under a protective strip to support said protective strip so that at least one part of said protective strip extends in a cantilevered fashion beyond said pillar; and
an organic layer having two distinct and separate portions, including a first portion continuously extending over each island and over each protective strip, and a second portion extending over the substrate without reaching said at least one cantilevered part of each protective strip.

Beneficially, the lateral gap of said at least one cantilevered part of each protective strip relative to the pillar supporting it is strictly greater than 100 nm.

Beneficially, said at least one pillar is made from an electrically insulating material.

Beneficially, said at least one pillar comprises a dielectric layer, for electrically insulating the islands separated by said at least one pillar; and a filling material, insulating or not, providing support to the protective strip, the dielectric layer of said at least one pillar separating the filling material of said at least one pillar from each island.

Beneficially, said at least one pillar has a continuous, ridge-less surface over which the protective strip extends, said continuous, ridge-less surface extending from the conductive layer of one of the islands to the conductive layer of another island, each continuous and ridge-less surface having a slope, measured relative to the substrate, between −45 degrees and 45 degrees and for example between −20 degrees and +20 degrees.

Another aspect of the invention further relates to a light-emitting display system, comprising:
a device according to the invention; and
an active addressing matrix comprising a plurality of transistors, each transistor of the plurality of transistors being connected to the conductive layer of one of the islands of said device.

The invention and its different applications will be better understood upon reading the following description and upon examining the accompanying figures.

### BRIEF DESCRIPTION OF THE FIGURES

The figures are set forth for by way of indicating and in no way limiting purposes of the invention. Unless otherwise specified, a same element appearing in different figures has a single reference number.

FIG. 1, FIG. 2 and FIG. 3 schematically show, in three views, one embodiment of a precursor to a display device according to the invention.

FIG. 4, FIG. 5 and FIG. 6 schematically show, in three views, a first step in a method for manufacturing the display device according to an embodiment of the invention.

FIG. 7, FIG. 8 and FIG. 9 schematically show, in three views, a second step in the method for manufacturing the display device according to an embodiment of the invention.

FIG. 10 and FIG. 11 schematically show, in two views, examples of protective strips according to embodiments of the invention.

FIG. 12 and FIG. 13 schematically show two other examples of protective strips according to embodiments of the invention.

FIG. 14, FIG. 15, FIG. 16 and FIG. 17 schematically show, in three views, a third step in the method for manufacturing the display device according to an embodiment of the invention.

FIG. 18, FIG. 19 and FIG. 20 schematically show, in three views, a fourth step in the method for manufacturing the display device according to an embodiment of the invention.

FIG. 21, FIG. 22 and FIG. 23 schematically show, in three views, a fifth step in the method for manufacturing the display device according to an embodiment of the invention.

FIG. 24, FIG. 25, FIG. 26, FIG. 27 and FIG. 28 schematically show four steps of one alternative of the manufacturing method according to an embodiment of the invention.

### DETAILED DESCRIPTION

The present invention aims to improve the manufacture of organic light-emitting display devices with improved resolution, also referred to as OLED (Organic Light-Emitting Diode) microdisplays.

In the following description, the term “pixel” designates a sub-pixel, i.e. the smallest element comprising a pixel of a light-emitting display device 200.

In an embodiment, pixels have lateral dimensions of less than 20 μm, or even less than 10 μm, for example between 5 μm and 1 μm, such as equal to 3 μm. They are, for example, arranged with a pitch of less than 20 μm, for example between 4 μm and 12 μm. Viewed from above, they have, for example, a rectangular shape, with a length: width ratio of about 3:1. The size of the pixels will hereinafter designate the side of the square.

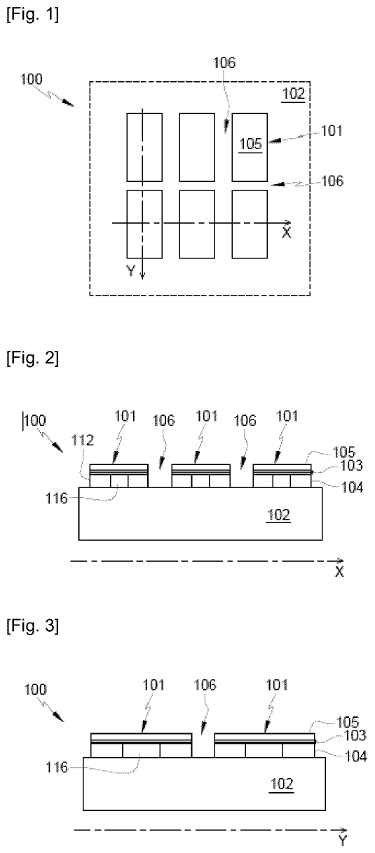

An embodiment of the present invention thus relates to a method for manufacturing a light-emitting display device from a precursor 100. An example of a precursor 100 is set forth in FIGS. 1 to 3. These figures show, especially, the precursor 100 in a top view (FIG. 1) and in two cross-sections (FIGS. 2 and 3) corresponding to the directions X and Y shown in FIG. 1.

In this example, the precursor comprises a substrate 102 and a plurality of islands 101. The islands 101 are to form the final pixels of the display device 200. They have a rectangular shape when viewed from above. Alternatively, they could have a square, triangular, hexagonal, circular or any other shape. They are disposed on the substrate 101 in groups of two, herein three groups of two islands. Each group of two islands forms a column and is, for example, aligned in parallel to the direction Y. A section of one of the groups of two islands 101 corresponds to the section in FIG. 3. The three columns (i.e. the three groups of two islands 101) are distributed along the orthogonal direction X. The islands 101 may, for example, also be aligned along the direction X thereby forming lines of islands 101. The islands 101 can be arranged along directions X or Y with a pitch of less than 20 μm, for example between 4 μm and 12 μm. Thus, the groups of islands can be arranged with a pitch of less than 20 μm, for example between 4 μm and 12 μm. Alternatively, the islands can be arranged differently. For example, the islands within a group can be arranged according to a hexagonal lattice (also called a honeycomb lattice). The pitch is then adapted to correspond to a hexagonal arrangement with a pitch of less than 20 μm, for example between 4 μm and 12 μm.

The substrate 102 is beneficially a specialised circuit or ASIC (Application Specific Integrated Circuit) of the CMOS (Complementary Metal Oxide Semiconductor) type. In this case, the substrate 102 is opaque and therefore beneficially adapted for manufacturing a light-emitting display device of the top-emitting type. In the following description, the terms “transparent” and “opaque” refer to an element which has an optical transmission coefficient greater than 60% and less than or equal to 60% respectively for at least one wavelength in the spectral band [400 nm; 1000 nm] or even [400 nm; 2000 nm].

It is noted that the substrate 102 may alternatively be made of amorphous silicon, polycrystalline silicon and/or deposited onto a glass plate. In the latter case, the substrate 102 may be transparent and therefore adapted for manufacturing a “bottom-emitting” type light-emitting display device.

The substrate 102 comprises an addressing circuit (not represented) configured to address the final pixels of the display device 200. The substrate 102 may also include an electrically insulating layer which may be an oxide, a nitride or an oxynitride. This insulating layer is, for example, formed from silicon nitride (SIN). The substrate 102 may further include a plurality of contact islands arranged across the insulating layer in order to make electrical contact with the final pixels of the device 200.

All islands 101 are separated from each other by at least trenches 106. The trenches 106 separate the columns of islands 101 and the rows of islands 101. In other words, within a group of islands 101, the islands 101 are separated by a trench 106. Each trench 106 is dug from the top of the islands 101 down to the substrate 102. The trenches 106 may partially separate the islands 101, for example by being dug only part of the way down the height of the islands (the islands 101 may share a bottom part, example). The trenches 106 may also be dug into the substrate 102 to improve insulation of the islands 101. The islands 101 may be arranged with a pitch of less than 20 μm, for example between 4 μm and 12 μm. The width of a trench 106 separating two adjacent islands 101 is, for example, between 0.3 μm and 1.5 μm.

The islands 101 of a same group (for example, of a same column) are, for example, intended to form pixels that will emit a same wavelength range. The three columns of islands 101 illustrated correspond, for example, to different wavelengths, such as the wavelengths corresponding respectively to blue, green and red.

Each island 101 has a mesa shape. That is, it is delimited by a single flank 112, extending from the substrate 101 to the top of the island 101. The flanks 112 of the islands furthermore form the edges of the trenches 106. Viewed from above, the islands 101 may have a rectangular shape with a height: width ratio of approximately 3:1 to within 10 %. The islands 101 may be square, hexagonal, circular or similar in shape. Each of them has a surface area, when viewed from above (FIG. 1), beneficially less than 40 μm², for example between 30 μm² and 1 μm², for example equal to 5 μm².

Each island 101 comprises a support layer 104 extending over the substrate 102. It extends directly against the substrate 102 or may be separated from the same by another layer (for example a diffusion barrier or a layer promoting particular crystallographic growth). The support layer 104 has a thickness H104 that can be between 150 nm and 1000 nm. The support layer 104 can be conductive, in which case it can be made from aluminium Al, copper-aluminium alloy AICu, chromium Cr or even silver Ag. Alternatively, it may be electrically insulating and in this case made from a dielectric such as silicon oxide SiO₂, silicon nitride SIN or aluminium oxide Al₂O₃.

Each island 101 also comprises a conductive layer 103. The conductive layer 103 is intended to form an electrode of the final pixel and herein a lower electrode. In the rest of the description, the conductive layer 103 may be referred to interchangeably as the “lower electrode”. The lower electrode 103 extends over the support layer 104. It extends directly against the support layer 104 or it may be separated from the same by another layer (such as a diffusion barrier or a layer promoting a particular crystallographic growth). The lower electrode 103 is for example parallel to the substrate 102.

The lower electrode 103 may be reflective, for example for a light-emitting display device of the “to-emitting” type. The support layer 104 is beneficially reflective or opaque. In top-emission, all or part of the support layer 104 may additionally be conductive. The support layer 104 comprises, for example, an insulating portion (surrounding, for example, contact members with a via located under the island). It may also be conductive. The term “reflective” designates a surface or element that has an optical reflection coefficient greater than 60% for at least one wavelength in the spectral band [400 nm; 1000 nm], or even [400 nm; 2000 nm]. The lower electrode 103 may be transparent for a “bottom-emitting” type light-emitting display device. In this case, the support layer 104 is beneficially transparent. It comprises, for example, an insulating portion (surrounding, for example, members for contacting a via located under the island) made of transparent dielectric material. However, the support layer 104 is beneficially conductive. It comprises, for example, a member for connecting the islands to a via located in the substrate 102 (see the conductive pillars 116 described below). It may also be entirely conductive.

The lower electrode 103 may alternatively comprise several stacked sub-layers. Each sub-layer is then formed of a different metal material or metal alloy. The metal material(s) (or metal alloys) used to form the first conductive layer 103 in an embodiment all have the property of being resistant to the etching chemistry of the support layer 104 and/or the structural element 107.

When the support layer 104 is insulating and comprises, for example, a dielectric such as SiO₂, the lower electrode 103 may be formed from a metal material or a conductive alloy. The lower electrode 103 comprises, for example, a stack of conductive sub-layers such as Ti/TiN/SnO₂. In this case, the thickness of the lower electrode 103 is in an embodiment greater than 20 nm, and for example between 40 nm and 100 nm. Alternatively, the lower electrode 103 may be formed from a Transparent Conductive Oxide (or TCO) to make a “bottom-emitting” light-emitting display device.

When the support layer 104 is conductive, the lower electrode 103 is in an embodiment formed from a transparent conductive oxide, for example Indium Tin Oxide (ITO), or zinc oxide (ZnO), aluminium-doped zinc oxide (AZO) or tin oxide SnO₂.

When the lower electrode 103 is a stack of conductive sub-layers, these sub-layers may be formed from titanium nitride TIN, tin oxide SnO₂, poly(3,4-ethylenedioxythiophene) (or PEDOT), or ITO, or zinc oxide (ZnO) or AZO. In an embodiment, the sublayer to be in contact with an organic layer is tin oxide SnO₂, while the sublayer in contact with the support layer 104 is titanium nitride TiN.

The lower electrode 103 in an embodiment has a thickness between 4 nm and 20 nm. When it comprises a stack of sub-layers, the thicknesses may vary as a function of the materials. For example, a TCO sublayer has a thickness of between 10 nm and 20 nm. A TiN sublayer has a thickness of less than 10 nm, for example between 4 nm and 8 nm.

The support layer 104 is intended to support the lower electrode 103. In other words, the support layer 104 is a connecting element between the substrate 102 and the lower electrode 103, which ensures that the lower electrode 103 is held on the substrate 102. The lower electrode 103 is therefore not in direct contact with the substrate 102.

The support layer 104 is at least partially conductive, so that it also serves to make an electrical connection between the lower electrode 103 and a contact pad or via located under the island (and therefore the final pixel). For each island 101, if the support layer 104 is not conductive, it may comprise a conductive pillar 116 (for example, the pillars are only represented in FIGS. 2 and 3), in contact with the lower electrode 103 and surrounded by a dielectric material (such as those previously mentioned). The presence of the dielectric material in this layer 104 provides or improves mechanical holding of the lower electrode 103.

To simplify the description, in the rest of the description, and unless otherwise stated, only two neighbouring islands 101 of a same column are considered. They correspond, for example, to the islands in FIGS. 3, 6, 9, 12, 13, 16, 19, 22, 24, 25, 26, 27 and 28. In other words, two neighbouring islands 101, separated by a same trench 106, are considered. The teachings hereinafter described can be transposed to a column of more than two islands 101; it suffices to consider the islands 101 two by two.

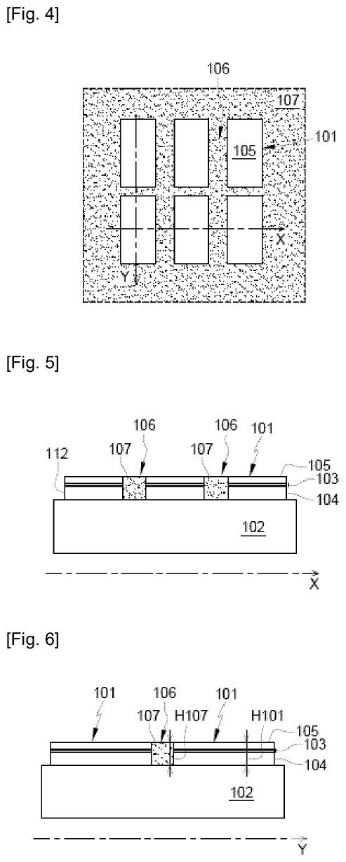

FIGS. 4 to 9 show a step of filling the trench 106, separating the two islands 101, by means of a structural element 107. This structural element 107 thus separates the two islands 101 while ensuring electrical insulation between them. The structural element 107 in an embodiment fills the entire trench 106 and is in direct contact with the two islands 101.

At the end of filling, the structural element 107 reaches the top of the two islands 101. In other words, the structural element 107 has a height H107, measured perpendicularly to the substrate 102 and from this substrate, greater than or equal to, and for example equal to, the heights H101 of the islands 101. The height H101 is, for example, measured from the substrate 102 to the top of each island 101.

In one mode of implementation, filling the trench 106 is performed until the conductive layers 103 are reached. By “the conductive layers are reached”, it is meant that the structural element 107 has a height, measured from the substrate 102, that allows it to be in direct contact with the conductive layers 103. In other words, the structural element 107 is flush with the conductive layers 103 or goes beyond the conductive layers 103. In an embodiment, the structural element 107 is flush with the conductive layers 103.

In one alternative of the method, detailed below, the islands 101 may comprise sacrificial layers 105, increasing the total height H101 of each island 101. In the presence of sacrificial layers 105, filling the trench 106 is performed until the top of the islands 101 is reached, i.e. the top of the sacrificial layers 105. From then on, the structural element 107 goes beyond the conductive layers 103.

According to this alternative, the difference in height between the structural element 107 and the conductive layers 103, H73=H107-H103, is greater than or equal to zero. The conductive layers 103 may be non-planar and have different heights. In this case, the heights are compared to the vertical of the flank 112 of the islands 101 and, in particular, to the vertical of the portion in contact with the structural element 107.

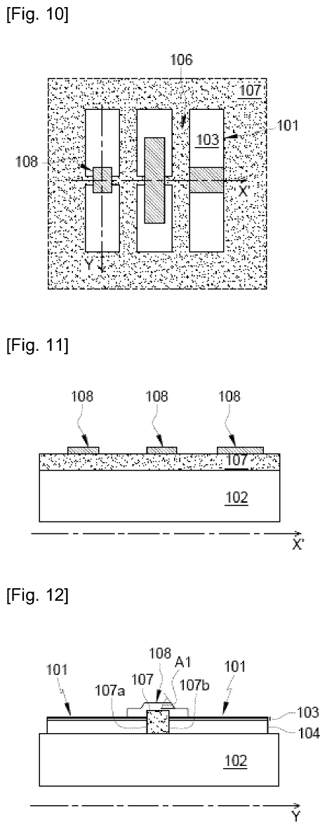

FIGS. 10 to 13 illustrate a protective strip 108. The protective strip 108 forms a bridge between the two islands 101 of a same column. It thus enables supporting a layer of organic material continuously extending and in one piece over the two islands 101.

The protective strip 108 is therefore a single, continuous layer, without any breaks or cuts, extending from one of the islands 101 to the other island 101. The protective strip 108 covers only part of each island 101. In this way, the layer of organic material can be in direct contact with the rest of each lower electrode 103.

The protective strip 108 also extends over the structural element 107 separating the two islands so as to cover at least part thereof. FIG. 10 illustrates three examples of protective strip 108. According to a first example, in a first column (left column), the protective strip 108 extends over a portion of the lower electrode 103 of one island 101 and extends along the direction Y to the other island 101 in the column. The mask 108 covers only a small portion of each island 101 and a small portion of the structural element 107. According to a second example, in a second (central) column, the protective strip 108 extends over a larger portion of each lower electrode 103, partly passing through the surfaces of these electrodes. According to a third example, in a third column (on the right), the protective strip 108 extends as an extension of the two islands 101, completely covering the structural element 107 that separates the two islands 101. FIG. 11 shows a cross-section of these different examples.

The protective strip 108 forms a bridge allowing continuous layers of material to be deposited onto two adjacent islands 101. It may be necessary to form a continuous layer over more than two islands 101, for example to connect all the islands belonging to a same column of islands 101. In this case, several protective strips 108 may be formed, each covering two neighbouring islands 101 as well as the structural element 107 separating them.

It may be beneficial for each protective strip 108 to be limited to only two neighbouring islands 101 (as well as the associated structural element 107). However, in order to form a continuous layer over more than two islands 101, the protective strip may be formed so as to cover each of these islands 101 while retaining a continuous, single-piece layer. Otherwise, it may be desirable for each protective strip 108 to be limited to only two islands 101 (and the associated structural element 107) and strictly these two islands 101.

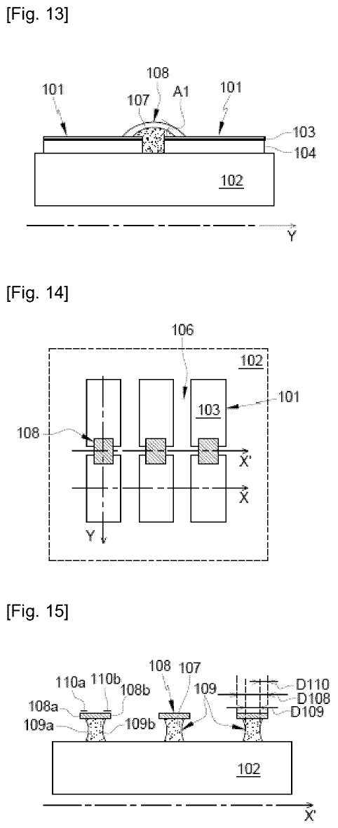

FIG. 12 shows an example of protective strip 108. This strip 108 corresponds, for example, to the example on the left in FIG. 10. The protective strip 108 covers part of each lower electrode 103 while straddling the structural element 107 separating these islands 101.

FIG. 13 shows another example of protective strip 108. This strip 108 may also correspond to the example on the left in FIG. 10. In this example, the structural element 107 partially protrudes from each island 101. Especially, it has an upper surface extending from a first lower electrode 103 to the other and forming a gentle slope. By “gentle slope”, it is meant a slope, measured with respect to the substrate 102, between −45 degrees and 45 degrees, for example between −20 degrees and +20 degrees, and in an embodiment between −5 degrees and +5 degrees. The protective strip 108 covers part of each lower electrode 103 and the structural element 107, also showing a gentle slope.

The protective strip 108 is in an embodiment electrically insulating in order to prevent a short circuit between the lower electrodes 103 of the islands 101 joined by this strip 108. It is, for example, made of aluminium oxide Al₂O₃ or SiO₂ or SiN. It is desirably resistant to the etching chemicals of the structural element 107.

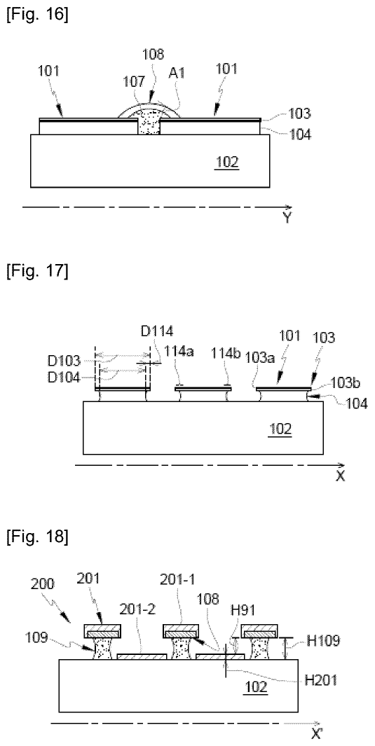

FIGS. 14 to 16 show the result of partially etching the structural element 107. Etching is made selectively relative to the protective strip 108. It also comprises at least one phase during which etching is isotropic. The isotropic etching phase removes all parts of structural element 107 that are not protected, especially by the protective strip 108. The trenches 106 are thus partially released. Etching, and especially its rate as well as its duration, are dimensioned so as to retain only a portion 109 of the structural element 107 under each protective strip 108, said portion 109 forming a pillar. FIG. 15 shows the result of partial etching relative to FIG. 11. In FIG. 11 (which corresponds to a cross-section along a trench 106), the structural element 107 occupies the entire trench 106. In FIG. 15, there are only three pillars 109, placed under each protective strip 108, which remain in the trench 106. The rest of the trench 106 is free. Partial etching may include only one etching phase and herein an isotropic etching phase. However, under some conditions, isotropic etching may remove the parts of the structural element 107 that are masked by the protective strip 108 too quickly. In order to remove the unmasked parts (for example: the parts exposed in the trench) more quickly so that only the pillar 109 under the strip 108 is retained, etching may comprise several etching phases. For example, it comprises at least one anisotropic etching phase and at least one isotropic etching phase, for example alternately (for example: anisotropic/isotropic/anisotropic/ . . . ). An isotropic etching phase follows an anisotropic etching phase. The anisotropic etching phases are performed with a directivity substantially perpendicular to the substrate. Thus, during these phases, only those parts of structural element 107 that are exposed (i.e. not masked by the strip) are attacked by etching. During the isotropic phases, the parts of structural element 107, even those disposed under strip 108, are etched. The exposed parts are thus attacked during both etching phases, while the masked parts are only attacked during the isotropic phase. The etching rate of the exposed parts is therefore increased relative to the etching rate of the masked parts.

The isotropic phase of partial etching can be performed in a wet environment, for example using hydrofluoric acid (HF) with an HF concentration of between 0.1 % and 2 % at room temperature. The isotropic phase can also be performed by dry isotropic etching, for example using SF₆ (to etch amorphous silicon) or HF (to etch Al₂O₃ without etching the amorphous silicon).

Partial etching leaves a pillar 109 under each strip 108. Each pillar 109 of the structural element 107 is delimited by a peripheral lateral surface, also referred to as a “flank”. Each pillar 109 is entirely delimited by a flank. In the example of FIGS. 4 to 16, the flank comprises four consecutive surfaces, including:
two surfaces opposite to each other and perpendicular to the axis Y; and
two other surfaces 109a, 109b, called “pillar sides”, also opposite to each other and perpendicular to the axis X′ (and X).

The two sides 109a, 109b of the pillar are additionally perpendicular to the trench 106, the same extending along the direction X′. As the structural element 107 initially fills the trench 106 separating the two islands, the surfaces perpendicular to Y are in contact with the islands 101. Conversely, the sides of pillar 109a, 109b, perpendicular to X′ and therefore to the trench 106, are free because they face the portions of the trench 106 that have been cleared by etching. Due to the isotropic etching effect, the sides of pillars 109a and 109b may have a concave shape, slightly entering the pillar 109.

Each protective strip 108 also has edges 108a, 108b extending perpendicularly to the direction X', i.e. perpendicular to the trench 106 it overlaps. The sides 109a, 109b of pillar 109 are substantially perpendicular to the edges 108a, 108b of the protective strip 108 supported by said pillar 109.

Since etching is performed selectively with respect to each protective strip 108, the edges of the strip 108a, 108b remain intact (or change very little). Partial etching is made so as to set back the sides 109a, 109b of each pillar 109 relative to the edges 108a, 108b of the protective strip 108. Thus, for each strip 108, the sides 109a, 109b of the pillar 109 supporting said strip 108 are disposed set back from the edges 108a, 108b of said strip 108. In this way, the protective strip 108 has two parts 110a, 110b extending in a cantilevered fashion beyond the pillar 109. The cantilevered parts 110a, 110b of the cantilevered strip 108 are thus vertically above the trench 106 and, more particularly, the substrate 102 exposed in the trench 106 during etching.

By “setback”, it is meant a lateral distance, measured along a direction X′ and parallel to the substrate 102, between one of the edges 108a, 108b of the protective strip 108 and the nearest side 109a 109b of the pillar 109. This setback corresponds to the advancement of the cantilevered part 110a, 110b of the protective strip 108. The setback is in an embodiment greater than 100 nm.

Partially etching the structural element 107 also has the effect of centring each pillar 109 under the protective strip 108 it supports. Thus, each pillar effectively bears the protective strip 108. The setback of the structural element 107 beneath the protective strip 108 allows a bridge to be formed connecting the two islands 101 and having cantilevered parts 110a, 110b vertically above the substrate 102.

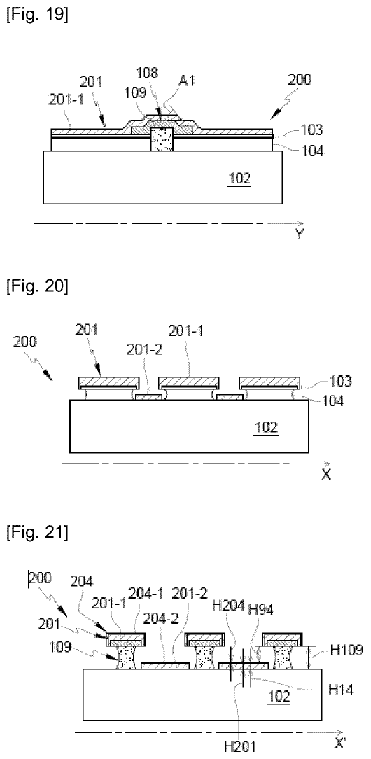

FIGS. 18 to 20 show the result of a deposition step, for example by evaporation, of an organic layer 201 intended to form an active element of the final pixel of the display 200. The organic material deposited is configured to generate electromagnetic radiation when an electric current passes therethrough. The emitted radiation may be white or an equivalent red, green or blue colour. The organic layer 201 may comprise a single layer configured to emit radiation having a spectrum located, for example, mainly in the blue, i.e. a spectrum extending over a wavelength range between 430 nm and 490 nm. Alternatively, the active layer 201 may comprise several emissive sub-layers to form a so-called “tandem” OLED structure (not represented). In this case, the organic layer 201 comprises several organometallic sub-layers, typically including two emissive organic sub-layers disposed one on top of the other and separated by organic functional layers of the charge transport, charge injection and/or charge generation type. In the following description, for the sake of simplicity, the term “organic layer” will be used to designate a homogeneous layer, a stack of organic sub-layers, or a stack of organometallic sub-layers.

The organic layer 201 is in an embodiment anisotropically deposited along a direction substantially perpendicular to the substrate 102. By “substantially perpendicular”, it is meant to being perpendicular to within +/−20 degrees. The deposition is a full-wafer deposition. By virtue of the removal of the pillar 109 supporting the protective strip, the organic layer 201 splits into two distinct portions 201-1 and 201-2. A first portion 201-1 extends over each island 101 and over the protective strip 108, acting as a bridge and connecting these islands 101. A second portion 201-2 of the organic layer 201 extends over the substrate 102, in the trenches 106 released by partially etching the structural element 107. Since the sides 109a, 109b of the pillars 109 are set back, no organic material accumulates against these sides. The sides 109a, 109b are protected by the cantilevered parts 110a, 110b of the protective strip 108. There is therefore no deposition of organic material that could form a link between the two portions 201-1, 201-2 of the organic layer 201. The cantilevered parts 110a, 110b of the protective strip 108, vertically above the substrate 102, cause the excess organic material to fall into the centre of the trenches 106 and away from the sides 109a, 109b of the pillar 109.

The organic layer 201 may slightly protrude onto parts 110a and 110b of the cantilevered protective strip 108, forming a cap that covers the upper part of the strip 108 as well as the edges 108a and 108b of the strip 108.

In order to ensure separation of the portions 201-1 and 201-2 of the organic layer 201, the thickness H201 of the organic layer 201 is in an embodiment less than the height H109 of the pillar 109. In this way, the second portion 201-2 of the organic layer 201, extending over the substrate 102, does not reach the protective strip 108 and especially its parts 110a, 110b, which are cantilevered above the second portion 201-2. Indeed, if the thickness reaches the height H109 of the pillar 109, organic layer 201 then reaches the edge of protective strip 108. Since the organic material can cover the edges of the strip 108, there is a high chance that continuity between the two portions 201-1 and 201-2 can be established. To ensure a sufficient margin, the height H109 of pillar 109 is in an embodiment greater than 1.2 times the deposition thickness H201 of the organic layer 201 and, for example, greater than 1.4 times or even greater than 2 times the deposition thickness H201 of the organic layer 201. The deposition thickness H201 is considered to be equal for both portions 201-1 and 201-2 of the organic layer 201, as these two portions 201-1 and 201-2 are deposited during the same step. The measurement of the deposition thickness H201 is in an embodiment carried out at a location where this thickness varies little, for example away from the edges. The organic layer 201 may have a deposition thickness H201 of between 100 nm and 200 nm.

The steps described previously thus make it possible to form a light-emitting display device 200. In the example of FIGS. 18 to 20, the device 200 comprises columns of pixels, each column of pixels being formed from a column of islands 101. The pixels are disposed on the substrate 102 and each comprise a support layer 104, a lower electrode 103 and an organic layer 201, continuously extending over the entire pixel column. In particular, considering only two of the pixels in a same pixel column, the device 200 comprises a trench 106 separating the two pixels and a pillar 109 disposed in that trench 106 and electrically insulating the two lower electrodes 103 of the pixels. An organic layer 201 extends over each lower electrode 103. A protective strip 108, forming a bridge joining the lower electrodes 103 of the two islands 101, and supported by the pillar 109, thus providing support for the organic layer 201, which extends along its entire length over the lower electrodes 103 of each pixel.

The different columns of pixels of the device 200 are separated from each other by trenches 106. The cantilevered parts 110a, 110b of the strip 108 allow the organic layer to be split into two separate portions 201-1, 201-2 distinct so that the portion 201-2 extending into the trench 106 is electrically insulated from the portion 201-1 extending over the islands 101.

In order to enhance the device 200, an additional step of depositing an additional conductive layer 204 may be performed. This additional conductive layer 204 may form an upper electrode for the final pixels. This upper electrode is in an embodiment transparent or semi-transparent, whether the lower electrode 103 is opaque or reflective. The term “semi-transparent” is meant for an element which, for at least one wavelength of the spectral band [400 nm; 1000 nm], or even [400 nm; 2000 nm], has an optical transmission coefficient of between 40% and 60%.

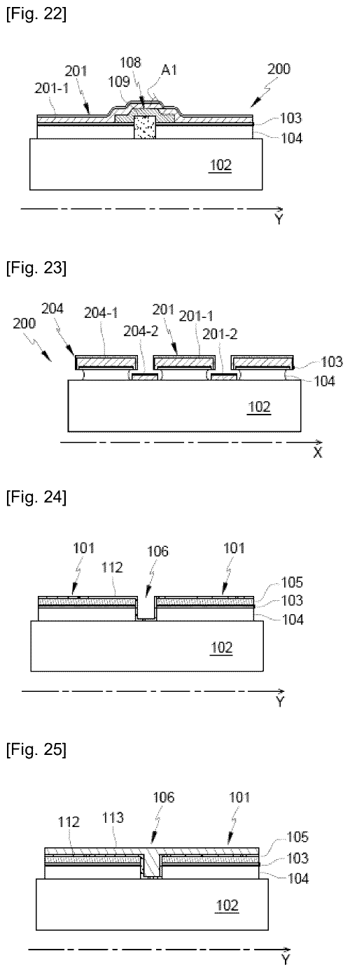

FIGS. 21 and 23 show the result of this additional step. The additional conductive layer 204 is made to have at least one portion 204-1 that completely covers the first portion 201-1 of the organic layer 201. Thus, this portion 204-1 of the additional conductive layer 204 forms an upper electrode of the device 200 and, especially, an upper electrode common to the column of islands 101. Thus, applying an electrical potential between the upper electrode 204-1 and one of the lower electrodes 103 allows an electrical field to be applied to a portion of the organic layer disposed between these two electrodes 204-1, 103. The additional conductive layer 204 is, for example, formed from a transparent conductive oxide (TCO) or a semi-transparent thin silver film or a semi-transparent thin aluminium film.

Depositing the additional conductive layer 204 is in an embodiment anisotropically performed with a direction substantially perpendicular to the substrate 102. Similar to the organic layer 201, the additional conductive layer 204 is split into two distinct portions 204-1, 204-2 that are separated from each other. A first portion 204-1 continuously extends over the first portion 202 of the organic layer 201 and forms the upper electrode. A second portion 204-2 of the additional conductive layer 204 extends into the trench 106 separating the island columns 101, and over the second portion 203 of the organic layer 201.

In order to ensure electrical insulation between these two portions 204-1, 204-2, depositing the additional conductive layer 204 is performed with a deposition thickness H204 such that the additional conductive layer 204 does not reach the protective strip 108 and in particular the cantilevered parts 110 of the strip 108. For example, the sum of the deposition thickness H201 of the organic layer 201 and the deposition thickness H204 of the additional conductive layer 204 is strictly less than the height H109 of the pillar 109 supporting the protective strip 108. To ensure a sufficient margin, the height H109 of the pillar 109 is in an embodiment greater than 1.2 times the sum of the thickness H201 of the organic layer 201 and the thickness H204 of the additional conductive layer 204, and for example greater than 1.5 times, or even greater than 2 times, the sum of these thicknesses H201 and H204. In other words, H109>1.2×(H201+H204), and in an embodiment H109>1.5×(H201+H204).

Complementarily, completing the device 200 may include depositing one or more encapsulation layers for protecting the oxidisable materials. This involves, for example, protecting the layers formed from aluminium oxide, silica or even nitride. The encapsulation layer or layers are formed, for example, by single-layer Atomic Layer Deposition (ALD) or Chemical Vapour Deposition (CVD).

FIGS. 12 and 13 show two examples of protective strip 108 that can be obtained at the end of the step of forming said strip 108. FIGS. 12 and 13 show a section made along a column of islands 101, thus showing the profile of strip 108 for each example.

In the case of FIG. 12, the structural element 107 underlying the strip 108 has a rectangular cross-section. The structural element 107 especially comprises two flanks 107a, 107b, each of which is in contact with one of the two islands 101 to be separated. These flanks 107a, 107b extend perpendicularly to the substrate 102 until they go beyond the tops of the islands 101. The portion of the structural element 107 going beyond the islands 101 thus has a step shape with sharp ridges. These ridges do not allow the formation of the organic layer 201. Indeed, the deposition of organic material on sharp ridges tends to break the resulting layer. It therefore no longer forms a continuous layer extending from one island 101 to another. To reduce this risk, the organic layer can be made very thick to eliminate presence of sharp ridges and breaks or fractures. However, an organic layer that is too thick tends to reduce effectiveness of the resulting device 200.

The protective strip 108 covers the structural element 107 by at least partly eliminating the sharp ridges of the same. The protective strip 108 is made, for example, by lithography, involving especially a material deposition step. This deposition covers the sharp ridges and forms a bridge overlapping the structural element 107, the free surface of this bridge being sufficiently “smooth” for the organic layer 201 to extend continuously, without breaks or cuts. By “smooth”, it is meant that the free surface has a tangent relative to the substrate (also referred to as a “slope” and depicted by the symbol A1 in FIG. 12) between −45°and 45°, in an embodiment between −20°and 20°, and for example between −5°and 5°.

FIG. 13 shows one embodiment in which the structural element 107 is modified so that it no longer has sharp ridges. Thus, the strip 108, extending directly against the structural element 107, has a free surface continuously extending from one island 101 to another, without edges or discontinuities. This embodiment is most likely to provide a bridge between the two islands, allowing a flawless organic layer to be formed. To obtain this strip 108, the structural element 107 undergoes creep or swelling to cause the portion of element 107 protruding from the islands onto the edge of these islands 101 to go beyond. This creep or swelling step thus softens or even eliminates the sharp ridges. The structural element 107 thus has a gentle slope, allowing a protective strip 108 with a similarly gentle slope to be formed. The creep or swelling can be made by heat treating the structural element 107. For example, the structural element 107 is heat treated at 200° C. for 30 minutes, followed by drying, in order to irreversibly set the deformation. The strip 108 can be formed in a second step, example by lithography.

FIGS. 1 to 3 show an alternative of the precursor 100 from which the display device 200 is formed. In this alternative, each island 101 comprises a sacrificial layer 105 extending over the lower electrode 103. It is formed, for example, from a dielectric material such as silicon oxide SiO₂, aluminium oxide Al₂O₃ and, in an embodiment, silicon nitride SiN. Silicon nitride SiN forms an effective barrier layer for performing a polishing step.

In the presence of the sacrificial layers 105, filling the trench 106 filled with the structural element 107 (as illustrated by FIG. 4 to 6) is performed so that the structural element 107 reaches the top of the sacrificial layers 105. For example, the material intended to form the structural element 107 is full-wafer deposited by filling the trenches 106 and covering the islands 101. Chemical Mechanical Planarisation (CMP) with stopping at the sacrificial layers 105 allows the top of the islands 101 to be exposed. Finally, etching of the sacrificial layer 105 following CMP allows the lower electrodes 103 to be cleared. This etching of the sacrificial layers 105 is in an embodiment performed selectively with respect to the structural element 107 and with stopping at the conductive layers 103. However, this etching retains a portion of the structural element 107, going beyond the islands 101 and in particular the conductive layers 103.

The thickness of the sacrificial layers allows the height H73 of structural element 107 going beyond the lower conductive layers 103 to be set. For each island, the sacrificial layer 105 has, for example, a thickness of between 10 nm and 100 nm, in order to correctly perform the role of a stop layer for a CMP step. Thus, the height H73 can be between 10 nm and 100 nm.

It will be appreciated that it is beneficial for the structural element 107 not to protrude from the lower electrodes 103. Thus, there are no ridges to be eliminated and making the strip 108 is simplified. The structural element 107 going beyond the lower electrodes 103 is a consequence of etching of the sacrificial layers 105.

However, it is contemplatable to etch the sacrificial layers 105 non-selectively with respect to the structural element 107. In this case, a larger or smaller portion of the structural element 107 is removed at the same time as the sacrificial layers 105. When the etching rate of the structural element 107 is equal to the etching rate of the sacrificial layers 105, for example to within 10%, the step of the structural element 107 (the part protruding from the conductive layers 103) is removed at the same time as the sacrificial layers 105. A step of reduced height may remain. However, if it has a height H73 of less than 30 nm, it has no effect on the formation of the organic layer 201.

In one alternative, the conductive layer 103 is sufficiently hard to act as a stop layer for CMP. In this case, the sacrificial layer 105 is not useful and the structural element 107 reaches the conductive layers 103 without going beyond them. The sacrificial layers 105 may also be sufficiently conductive that they do not need to be removed. They can therefore be integrated into the final pixels, as if they were part of the conductive layers 103.

In FIGS. 4 to 9, the structural element 107 is made of an electrically insulating material. Examples include silicon oxide SiO₂, silicon nitride SiN, and aluminium oxide Al₂O₃. Alternatively, the structural element 107 may be a polymer-based material such as a resin (especially with a view to performing a step of creeping or swelling the structural element 107). The structural element 107 is even in an embodiment comprised of a same electrically insulating material such as those mentioned above.

Filling is, for example, performed by depositing the insulating material so as to completely fill the trench 106. Filling is, for example, made by full-wafer deposition of the electrically insulating material (or polymer) followed by polishing (also referred to as “planarisation”) with stopping at the sacrificial layers 105 (in an embodiment of SiN). Before forming the protective strip 108 and in the hypothesis that the sacrificial layers 105 are insulating, said sacrificial layers 105 are in an embodiment removed according to the procedure described previously.

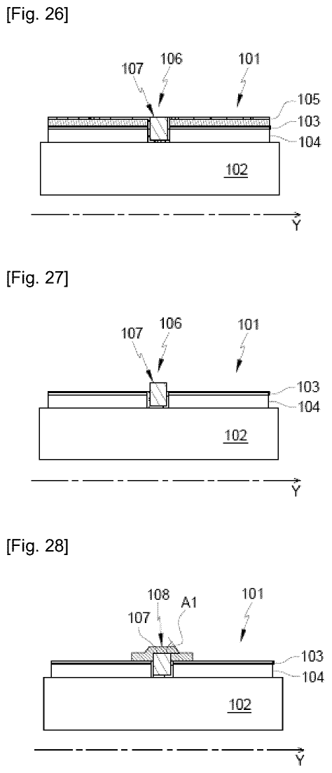

FIGS. 24 to 27 show one alternative of the manufacturing method and especially for the structural element 107. The latter is not made of a homogeneous, electrically insulating material. It comprises two materials: a first, dielectric, material allowing the islands to be electrically insulated from each other; and a second, so-called “filling” material, which may or may not be insulating, and whose role is therefore to fill the trench 106 to provide support for the protective strip 108. The first dielectric material extends, for example, against each of the islands separated by the structural element.

FIG. 24 shows, for example, a passivation of the precursor 100 of FIGS. 1 to 3. The passivation layer 112 continuously extends over the islands 101 and into the trench 106 separating these islands 101. The passivation layer 112 especially covers the sacrificial layers 105 extending over the lower electrodes 103.

FIG. 25 shows filling the trench 106 passivated. The filling material 113 is full-wafer deposited so as to completely fill the trench 106 and go beyond it.

FIG. 26 shows polishing the stack of FIG. 25, with stopping at the sacrificial layers 105. The filling material 113 and the passivation layer 112 outside the trench 106 are thus removed. The resulting structural element 107 then comprises: a dielectric layer, corresponding to the passivation layer 112 and lining the bottom and sides of the trench 106; and a filling material 113 filling the rest of the trench 106.

Unlike the structural element 107 in FIG. 4 to 6, the structural element 107 is not necessarily completely electrically insulating. Indeed, the passivation layer 112 is sufficient to make electrical insulation between the islands 101. The filling material 113 is therefore not necessarily insulating. It may also be electrically conductive. For example, it may be made of amorphous silicon or polycrystalline silicon.

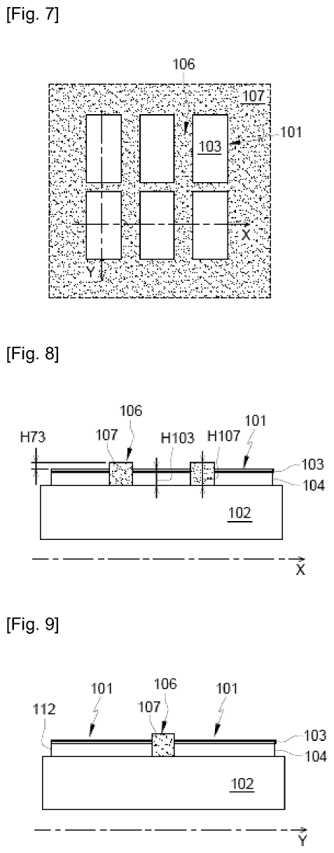

The step of removing the sacrificial layers 105 is performed selectively with respect to the structural element 107 in FIGS. 7 to 9. This may also be the case with the structural element 107 in FIG. 26. However, in one alternative illustrated by FIG. 27, removing the sacrificial layers 105 may be performed selectively with respect to the filling material 113 of the structural element 107. Thus, the passivation layer 112 may be removed for only the filling material 113 to go beyond. FIG. 28 shows an example of a protective strip 108 covering the structural element 107 and in particular the filling material 113 of this element 107. In the event that the filling material 113 is electrically conductive, then the protective strip 108 is necessarily electrically insulating.

FIG. 17 shows an alternative embodiment of partially etching the structural element 107. Indeed, etching of the structural element 107 can be made isotropically and selectively with respect to the protective strip 108 and the lower electrodes 103. Thus, the lower electrodes 103 remain intact while the exposed parts of the support layers 104 (i.e. those likely to be exposed to isotropic etching) can also be partially etched. After this etching, each support layer 104 then shows a setback D114 relative to the edges 103a, 103b of the lower electrodes. Each lower electrode 103 then has cantilevered parts 114a, 114b. These cantilevers are vertically above the substrate 102.

FIGS. 20 and 23 show the result of the steps of depositing the organic layer 201 and the additional conductive layer 204. Following the same principle as for the protective strips 108, the cantilevered parts 114a, 114b allow the organic layer 201 and the conductive layer 204 to be formed by splitting these layers into two distinct portions. Thus, these layers 201, 204 can be deposited onto several columns of islands 101 at the same time without there being any electrical contact between the columns. On the other hand, the layers 201, 204 can continuously extend over each column of islands 101. The deposition thicknesses H201, H204 of layers 201, 204 are restricted so that, when they form a stack in a trench 106, they cannot reach the lower electrodes 103 and in particular the cantilevered parts 114. Thus, the sum of the deposition thicknesses H201 and H204 is in an embodiment strictly less than the height of the support layers 104 (the latter normally being less than the height of the pillars 109).

The display device 200 resulting from the method detailed above thus comprises several pixels, each comprising a lower electrode 103 and an organic layer 201 extending over each lower electrode 103. Device 200 is unique in that the organic layer 201 continuously extends, in a single piece, over the plurality of pixels. This is made possible by virtue of one or more protective strips 108 that form a bridge between the pixels. The plurality of pixels may also have, at a more advanced stage, an upper electrode 204, common to all pixels, extending, like the organic layer 201, continuously and in one piece over the plurality of pixels.

The protective strip(s) 108, and even the lower electrodes 103, have cantilevered peripheral parts, which minimise the risk of manufacturing defects while relaxing one of the manufacturing restrictions, namely the angle of deposition of the organic material 201 and the upper electrode 204.

In the different embodiments set forth, the islands 101 have distinct lower electrodes 103. However, some islands could have common lower electrodes 103. For example, in FIG. 1, the islands 101 can be gathered by colour group. Islands 101 of a same colour are, for example, aligned by column, i.e. along the direction Y. Herein, FIG. 1 shows three columns of pixels that may correspond to three distinct colours. At the end of the method, the upper electrode 204 may be common to several islands 101, for example the islands in a same column. The upper electrode 204 continuously extends along the direction Y, for example. This pixel arrangement is called a “strip” arrangement.

In one development, the lower electrode 103 may be formed so as to extend over several islands 101. However, in order to be able to distinctly address each pixel, it is beneficial for the common lower electrode 103 not to connect the same islands as the common upper electrode 204. For example, the lower electrodes 103 may connect pixels belonging to different columns. For example, in FIG. 1, the islands could be connected by two lower electrodes 103 extending perpendicularly to the columns, i.e. along X. One of the lower electrodes 103 connects, for example, the three upper islands 101, while the other lower electrode 103 connects the three bottom islands 101. Thus, the common lower and upper electrodes 103, 204 form a network of intersecting electrodes, generally referred to as a “cross-bar”, allowing the pixels to be addressed one by one.

A device 200 resulting from the method according to the invention can beneficially be integrated into a display system, such as an electronic apparatus screen, comprising an addressing matrix. The addressing matrix is, for example, partly disposed in the substrate 102. It is then configured to address each lower electrode 103 of the pixels. It comprises, for example, electrodes extending into the substrate and opening onto the surface of the substrate 102, each support layer 104. The support layer 104, being conductive or comprising at least one conductive portion (such as portion 116 in FIG. 2 and FIG. 3), enables connection between the lower electrodes 103 and the addressing matrix.

The addressing matrix may be a so-called “passive” matrix. It comprises, for example, a plurality of intersecting conductive lines, each pixel being connected at the intersection between two conductive lines. However, in one beneficial development, the intersecting conductive lines may be formed by:
the upper electrodes 204, extending, for example, along one direction (for example Y) and common to several pixels; and
lower electrodes 103, extending perpendicularly to the upper electrodes 204 (for example along the direction X) and common to several pixels.

The addressing matrix may be a so-called “active” matrix. It allows the formation of an AMOLED (Active Matrix Organic Light-Emitting Diode) display system. The active matrix allows each pixel to be independently controlled. It comprises a plurality of Thin-Film Transistors (TFTs). Each TFT is connected to a lower pixel electrode 103 so that each pixel can be independently controlled. In one embodiment, the upper electrodes 204 are connected to a common cathode, for example at the edge of the matrix.

Expressions such as “comprise”, “include”, “incorporate”, “contain”, “is” and “have” are to be construed in a non-exclusive manner when interpreting the description and its associated claims, namely construed to allow for other items or components which are not explicitly defined also to be present. Reference to the singular is also to be construed in be a reference to the plural and vice versa.

The articles “a” and “an” may be employed in connection with various elements and components, processes or structures described herein. This is merely for convenience and to give a general sense of the processes or structures. Such a description includes “one or at least one” of the elements or components. Moreover, as used herein, the singular articles also include a description of a plurality of elements or components, unless it is apparent from a specific context that the plural is excluded.

As used herein in the specification and in the claims, the phrase “at least one”, in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

A person skilled in the art will readily appreciate that various features, elements, parameters disclosed in the description may be modified and that various embodiments disclosed may be combined without departing from the scope of the invention. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Having described above several aspects of at least one embodiment, it is to be appreciated various alterations, modifications, and improvements will readily occur to those skilled in the art. Such alterations, modifications, and improvements are intended to be aspects of this disclosure. Accordingly, the foregoing description and drawings are by way of example only.

1. A method (300) for manufacturing a light-emitting display device (200) from a precursor (100), said precursor (100) comprising a plurality of islands (101) disposed on a substrate (102), each island (101) comprising a support layer (104) extending over the substrate (102); and a conductive layer (103) extending over the support layer (104), the islands being separated two by two by a trench (106), the method (300) comprising:
filling each trench (106) separating the islands (101) with a structural element (107) electrically insulating the islands (101), for each trench (106), filling being performed until said structural element (107) reaches the top of the islands (101) separated by said trench (106);
forming at least one protective strip (108), each protective strip (108) connecting two islands (101) between them by overlapping the trench (102) separating said two islands (101) and by covering the structural element (107) extending in the trench (106), each protective strip (108) only partly covering each of the two islands (101) that it connects;
partially etching the structural element (107) selectively with respect to each protective strip (108) and with respect to the conductive layers (103) of the islands (101), partially etching comprising at least one isotropic etching phase, partially etching being performed so as to retain only a portion (109) of the structural element (107) disposed under each protective strip (108) and said portion (109) forming a pillar for each protective strip (108), partially etching being further performed so that at least one part (110a, 110b) of each protective strip (108) extends in a cantilevered fashion beyond the pillar (109) supporting it; and
anisotropically depositing an organic layer (201) at an angle substantially perpendicular to the substrate (102), resulting in two portions (201-1, 201-2) distinct and separate from the organic layer (201), including a first portion (201-1) continuously extending over each island (101) and over each protective strip (108), and a second portion (201-2) extending over the substrate (102), a deposition thickness of the organic layer (201) being selected such that the second portion (203) of the organic layer (201) does not reach said at least one cantilevered part (110a, 110b) of each protective strip (108).

2. The method (300) according to claim 1, wherein partially etching the structural element (107) is performed such that the lateral gap (D110) of said at least one cantilevered part (110a, 110b) of each protective strip (108) relative to the pillar (109) supporting it is strictly greater than 100 nm.

3. The method (300) according to one of claims 1 or 2, wherein for each trench (106), filling is performed until the structural element (107) goes beyond the conductive layers (103) of the two islands (101) separated by said trench (106) by a height of between 10 nm and 100 nm.

4. The method (300) according to claim 3, wherein each island (101) comprises, prior to filling each trench (106), a sacrificial layer (105) extending over the conductive layer (103), filling each trench (106) with the structural element (107) being performed such that the structural element (107) reaches the top of the sacrificial layers (105) extending over the islands (101).

5. The method (300) according to claim 4, further comprising, after filling each trench (106) and before forming each protective strip (108), etching the sacrificial layer (105) of each island (101) selectively relative to the structural element (107), etching being performed with stopping at said conductive layer (103) of said island (101).

6. The method (300) according to one of claims 4 or 5, wherein, for each trench (106), filling with the structural element (107) comprises:
depositing a layer of electrically insulating material so as to completely fill said trench (106);
polishing the layer of insulating material with stopping at the sacrificial layer (105) of each island (101).

7. The method (300) according to one of claims 4 or 5, wherein, for each trench (106), filling with the structural element (107) comprises the following steps of:
conformally depositing a dielectric layer in said trench (106);
depositing a layer of filling material onto the dielectric layer so as to completely fill said trench (106);
polishing the dielectric layer and the filling layer with stopping at the sacrificial layer (105) of each island (101).

8. The method (300) according to claim 7, wherein the filling material is amorphous silicon or polycrystalline silicon.

9. The method (300) according to one of claims 1 to 8, comprising, prior to forming each protective strip (108), creeping or swelling the structural element (107) so that it goes over a portion of the conductive layer of each island (101), forming at least one continuous, ridge-less free surface extending from the conductive layer (103) of one of the islands (101) to the conductive layer of another island (101), each free surface having a slope, measured relative to the substrate (102), of between −45 degrees and 45 degrees and preferably between −20 degrees and +20 degrees.

10. The method (300) according to one of claims 1 to 9, wherein each protective strip (108) is electrically insulating.

11. The method (300) according to one of claims 1 to 10, wherein partially etching the structural element (107) comprises at least one anisotropic etching phase and at least one isotropic etching phase, for example alternately, each anisotropic etching phase being performed with a directivity substantially perpendicular to the substrate (102).

12. The method (300) according to one of claims 1 to 11, comprising, after depositing the organic layer (201), anisotropically depositing an additional conductive layer (204), resulting in two portions (204-1, 204-2) distinct and separate from the additional conductive layer (204), including a first portion (204-1) of the additional conductive layer (204) continuously extending over the first portion (201-1) of the organic material layer (201), and a second portion (204-2) of the additional conductive layer (204) extending over the second portion (2021-2) of the organic layer (201), a deposition thickness of the additional conductive layer (204) being selected such that the second portion (204-2) of the additional conductive layer (204) does not reach said at least one cantilevered part (110a, 110b) of each protective strip (108).

13. The method (300) according to one of claims 1 to 12, wherein partially etching the structural element (107) is further performed so as to partially etch the support layer (104) of each island (101) such that, for each island (101), at least one part (114) of the conductive layer (103) of said island (101) extends in a cantilevered fashion beyond the support layer (104) of said island (101).

14. A light-emitting display device (200) comprising a plurality of islands (101) disposed on a substrate (102), each island comprising a support layer (104) extending over the substrate (102) and a conductive layer (103) extending over the support layer (104), the device comprising:
at least one trench (106) separating the islands (101) two by two;
at least one protective strip (108), each protective strip (108) connecting two islands (101) to each other by overlapping the trench (102) separating said two islands (101), each protective strip (108) only partly covering each of the two islands (101);
at least one pillar (109) at least partly filling a trench and electrically insulating the islands (101) separated by said trench (106), each pillar (109) reaching or going beyond the top of the two islands (101) separated by said trench (106), each pillar being disposed under a protective strip (108) to support said protective strip (108) such that at least one part (110a, 110b) of said protective strip (108) extends in a cantilevered fashion beyond said pillar (109); and
an organic layer (201) having two portions (201-1, 201-2) distinct and separate from each other, including a first portion (201-1) continuously extending over each island (101) and over each protective strip (108), and a second portion (201-2) extending over the substrate (102) without reaching said at least one cantilevered part (110a, 110b) of each protective strip (108).

15. The display device (200) according to claim 14, wherein the lateral gap (D110) of said at least one cantilevered part (110a, 110b) of each protective strip (108) relative to the pillar (109) supporting it is strictly greater than 100 nm.

16. The display device (200) according to one of claims 14 or 15, wherein said at least one pillar (109) is made from an electrically insulating material.

17. The display device (200) according to one of claims 14 to 16, wherein said at least one pillar (109) comprises a dielectric layer, for electrically insulating the islands (101) separated by said at least one pillar (109); and a filling material, serving as a support for the protective strip (108), the dielectric layer of said at least one pillar separating the filling material of said at least one pillar from each island (101).

18. The display device (200) according to any of claims 14 to 16, wherein said at least one pillar (109) has a continuous, ridge-less surface over which the protective strip (108) extends, said continuous, ridge-less surface extending from the conductive layer (103) of one of the islands (101) to the conductive layer of another island (101), each continuous, ridge-less surface having a slope, measured relative to the substrate (102), between −45 degrees and 45 degrees and preferably between −20 degrees and +20 degrees.

19. A light-emitting display system, comprising:
a device (200) according to one of claims 14 to 18; and
an active addressing matrix comprising a plurality of transistors, each transistor of the plurality of transistors being connected to the conductive layer (103) of one of the islands (101) of said device (200).
